(19) United States
(12) Patent Application Publication
(10) Pub. No.: US 2013/0242501 A1
(43) Pub. Date: Sep. 19, 2013

(54) Node Module and Base Thereof

(71) Applicants: Yaw-Song Chen, Taipei City (TW); Chiang-Ko Chen, Taipei City (TW); Wen-Fu Wen, Taipei City (TW)

(72) Inventors: Yaw-Song Chen, Taipei City (TW); Chiang-Ko Chen, Taipei City (TW); Wen-Fu Wen, Taipei City (TW)

(21) Appl. No.: 13/484,342

(22) Filed: May 31, 2012

(30) Foreign Application Priority Data
Mar. 15, 2012 (TW) 101108917

(51) Int. Cl. G06F 1/16; H05K 7/20; H05K 5/02; H05K 7/00; H05K 5/00

(52) U.S. Cl. 361/679.33; 361/807; 361/752; 361/679.02; 312/326; 312/236

(57) ABSTRACT

A base and a module for node modules are disclosed. The base includes a first container, a second container, and a rotation portion connected with the first container and the second container respectively, wherein the first container and the second container are substantially the same and adjacent to each other. When the first container is rotated forward to the second container, the first container is stacked on the second container, and the total height of the first container and the second container is 2U.

### TECHNOLOGY FIELD

The disclosure is related to a node module and base thereof.

### BACKGROUND

A computer cluster, usually called a cluster, is a type of computer system composed of a set of loosely coupled computer software and/or hardware to complete computation tasks under high cooperation. One single computer in a cluster system is usually called a node, and a node is connected with a local area network but can also be connected with other connecting methods. Cluster computing is usually used for improving the computation speed and/or reliability of a single computer.

Due to the growth of information technology systems, more servers are needed. However, due to limited space in some organizations, the capacity of rack shelves is insufficient, and thus the number of servers cannot be increased as desired.

The rack unit is a standard size unit for servers defined by Electronic Industrial Association (EIA) of the United States. One rack shelf unit, called “1U”, is 1.75 inches (about 44.5 cm) high by 19 inches wide. Two rack shelf units, called “2U”, have an actual height of 1.75×2 inches (about 89 cm) and the same width of 19 inches. The same pattern of height increases extends to other units (3U, 4U, 5U, . . . ). Therefore, different system elements disposed within N rack shelf units need to be compatible with a corresponding fixed height to be in compliance with the general standard.

For providing higher density computation, it is necessary to increase the number of real servers within limited rack shelf space. Therefore, many manufacturers have begun installing more real servers in the same rack shelf height, using blade servers and multi-motherboard servers. However, these conventional approaches are still limited by space and the lack of sufficient flexibility. Related elements are fixed, and the system elements cannot be dynamically arranged. Only fixed computation modules (motherboards, processors, memory) can be installed. It is not possible to increase rack shelf utilization under the 2U/4U/5U/6U spatial construct and to achieve flexible system arrangement at the same time.

In addition, when servers are limited to a fixed height, scalability and heat dissipation face certain limitations. In some cases, certain elements also need to be installed, instead of complete equipment expansion. Therefore, the capability of a single machine is limited, and its application is also limited to a certain field.

### SUMMARY

An objective of the present invention is to provide a base that can be adjusted to accommodate different high performance computation node modules in a limited space.

Another objective of the present invention is to use the base to provide variable high computation performance modules.

To achieve the aforementioned objectives, the embodiment of the present invention provides a base for a node module that includes a first container, a second container, and a rotation portion. The first container is used for disposing a system allocation unit of the node module, and the second container is used for disposing another system allocation unit of the node module. The size of the second container is substantially the same as the first container, and the first container is aligned to be adjacent to the second container. The rotation portion is respectively connected to the first container and the second container such that the first container is able to be rotated with respect to the second container and to be stacked on the second container. In a preferred embodiment, after rotating, the total height of the first container and the second container is 2U.

Moreover, the base of the node module further includes a fan to be disposed on the first container or the second container.

In one embodiment, the first container and second container are respectively disposed with a first hard disk and a second hard disk. In addition, any one of the first container and the second container is equipped with a latch for controlling the ejection of the first hard disk or the second hard disk from the first container or the second container respectively.

The embodiment of the present invention also provides a system allocation module which includes the base as mentioned above, and the first container and the second container are used to dispose any one of the following: a multiple motherboards computing unit, a general purpose computing on graphics processing unit (GPGPU), a storage unit, and a small form factor PCI Express module (SXM) unit. The present invention also provides a node module that includes two of the aforementioned node module bases, multiple system allocation units, and a power supply. The power supply is located between two bases for providing power to each system allocation unit. The system allocation unit includes at least a multiple motherboards computing unit, a general purpose computing on graphics processing unit (GPGPU), a storage unit, and/or a small form factor PCI Express module (SXM) unit.

### BRIEF DESCRIPTION OF THE DRAWINGS

FIG. 1 illustrates a base for a high computation node module;

FIGS. 1A-1D illustrate different node modules used in high performance computation;

FIG. 2 illustrates the appearance of a node module of FIG. 1A after folding;

FIG. 3 is an embodiment of the present invention illustrating two sets of node modules of FIG. 2;

FIG. 4 illustrates five sets of node modules of FIG. 2 installed on a rack shelf; and

FIG. 5 and FIG. 6 illustrate assembly of multiple sets of node modules of FIG. 2.

### DETAILED DESCRIPTION OF EMBODIMENTS

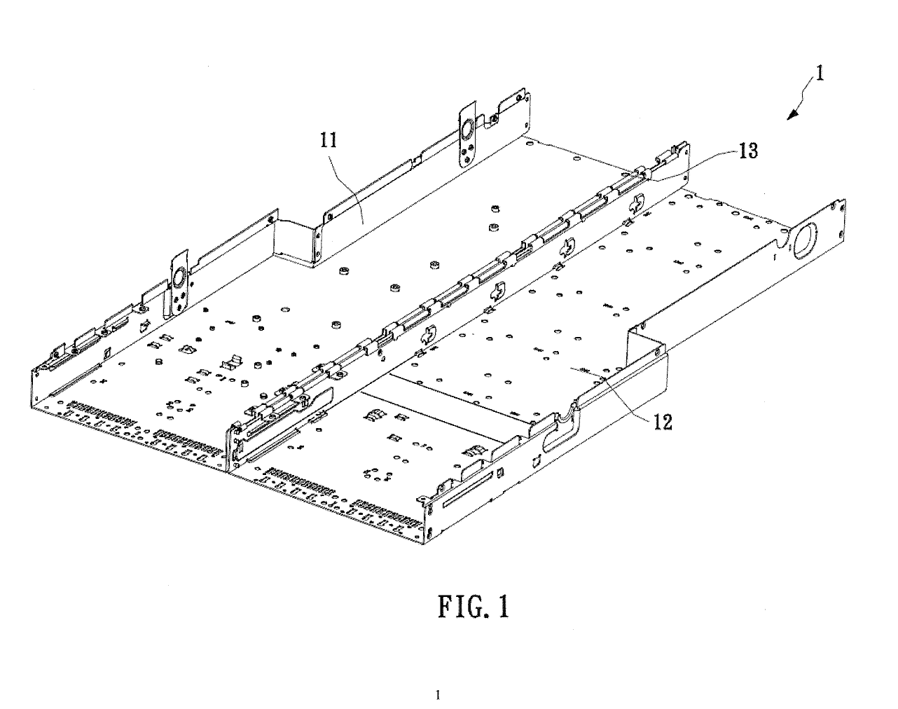

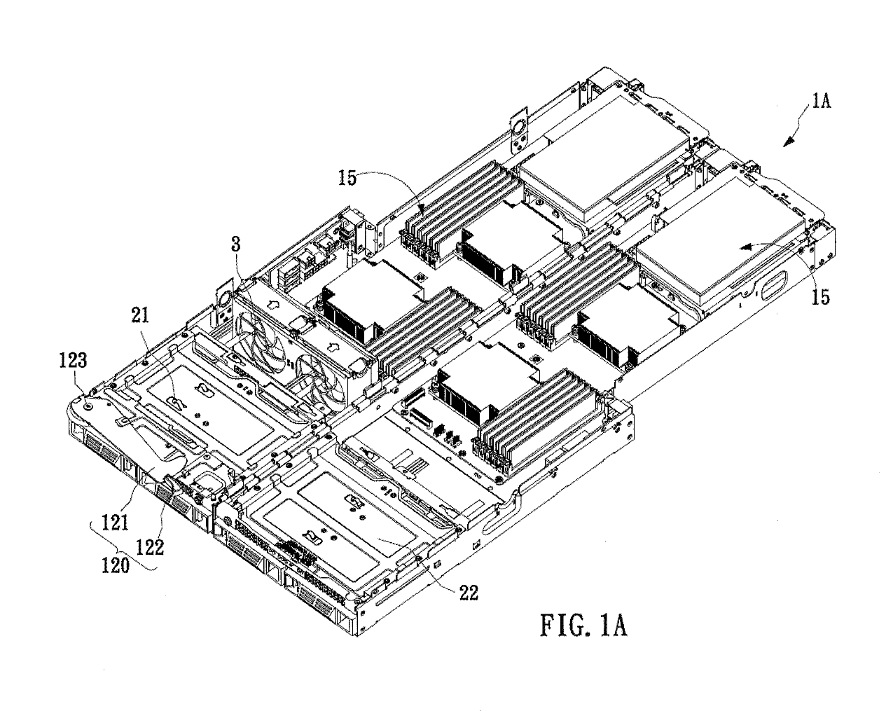

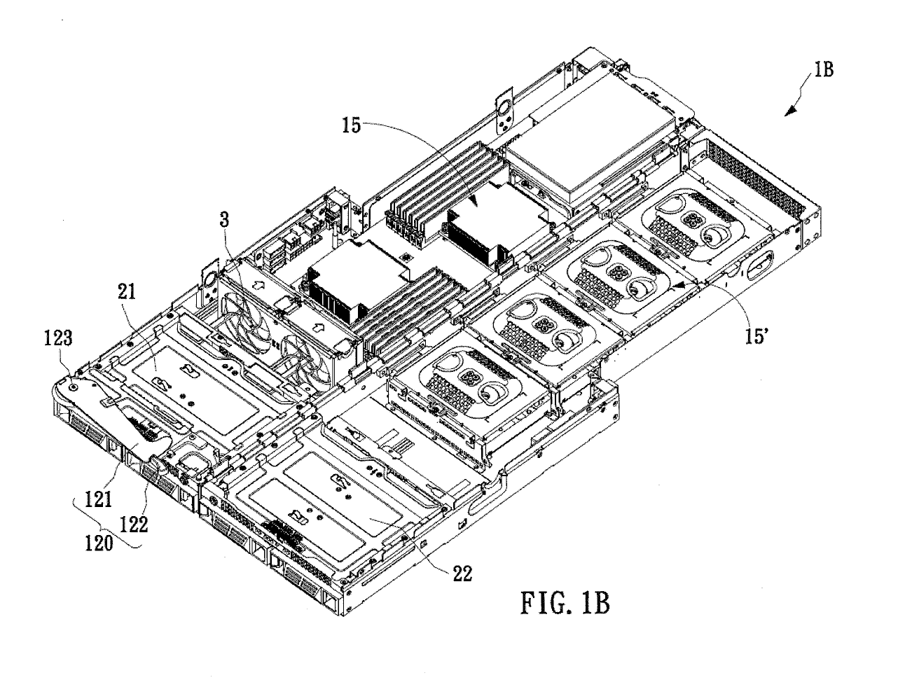

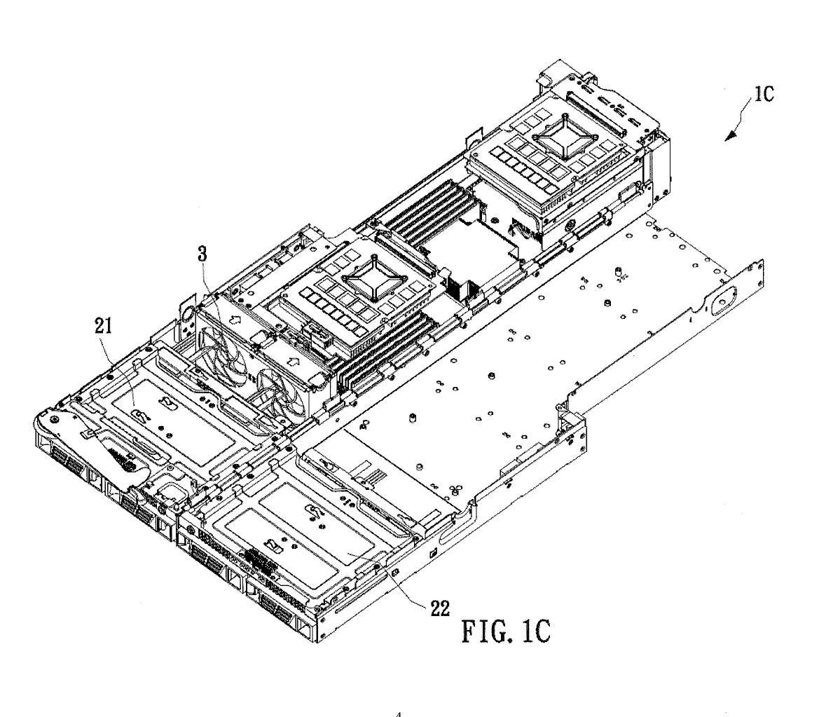

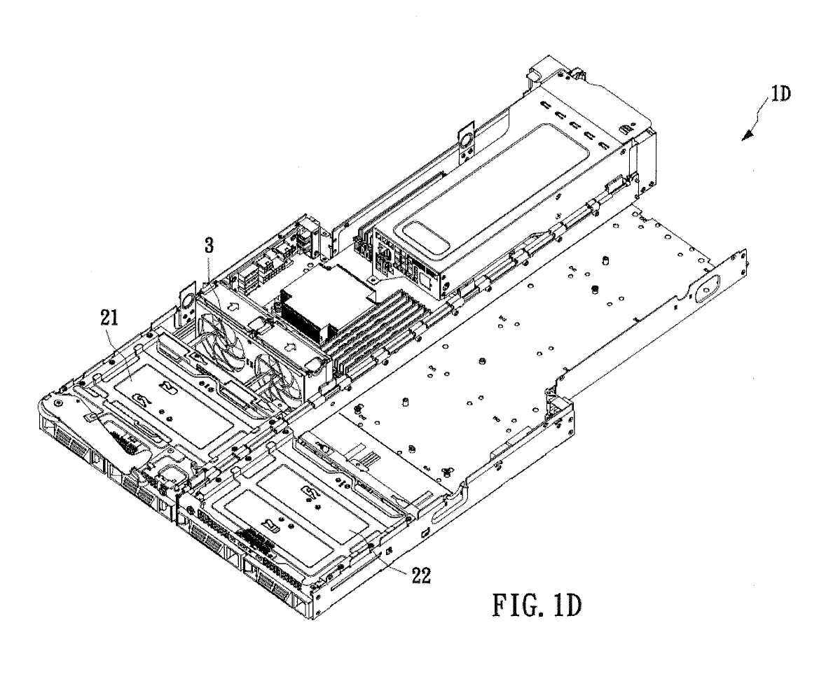

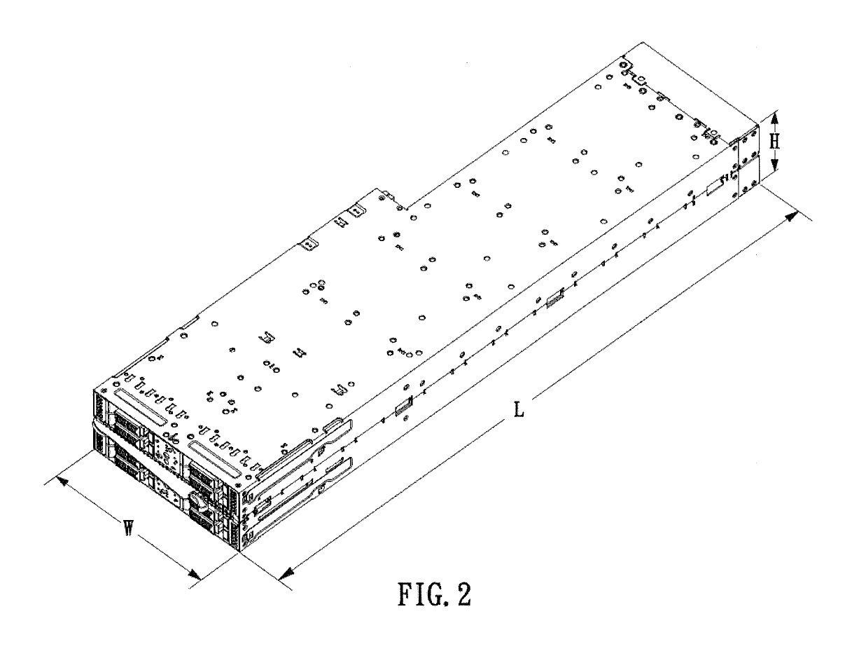

For clearer explanation of the spirit of the present invention, please refer to FIG. 1, which illustrates a preferred embodiment. The present invention provides a base 1 for a node module. The base 1 includes a first container 11, a second container 12, and a rotation portion 13. The first container 11 is substantially the same as the second container 12, and the first container 11 is aligned to be adjacent to the second container 12. As illustrated in FIG. 2, the rotation portion 13 is connected to the first container 11 and the second container 12 respectively such that the first container 11 can be rotated with respect to the second container 12 with a folding rotation. After such rotation, the first container 11 is stacked on the second container 12, and the total height of the first container 11 and the second container 12 after being stacked is 2U, which is about 1.75 inches. In this embodiment, the rotation portions 13 are multiple hinges arranged in parallel. However, please note that such a design is not to limit the scope of the invention. For example, the rotation portion 13 can also be a single long type rotation axial shaft (not shown).

As illustrated in FIG. 1, the first container 11 and the second container 12 have one side slightly wider than the other side. Specifically, the sides of the first container 11 and the second container 12 that are set with hard disks 21 and 22 (shown in FIG. 1A) are slightly wider than the other sides. When the first container 11 and the second container 12 are aligned without being rotated and stacked, the first container 11 and the second container 12 together form a T-shape from the top view.

Please refer to FIG. 1A. The first container 11 is used for installing a system allocation unit 15, and the second container 12 is used for installing another system allocation unit 15. In this embodiment, the first container 11 and the second container 12 are installed with same system allocation units. Please refer to FIG. 1B. The first container 11 and the second container 12 are installed with different system allocation units 15 and 15′. In other words, the first container 11 is installed with a system allocation unit 15 and the second container 12 is installed with another system allocation unit 15′.

In addition, as illustrated in FIG. 1A and FIG. 1B, the base 1 of the node module further includes a fan 3. The fan 3 can be disposed on the first container 11 or the second container 12. Therefore, heat from heating elements that need heat dissipation, such as CPUs, can be dissipated by the fan 3.

Please refer to FIG. 1A and FIG. 1B. The first container 11 is installed with a hard disk 21, and the second container 12 is installed with a second hard disk 22. The first hard disk 21 and the second hard disk 22 can be the same or not the same hard disks. For example, they can be the same or different 2.5-inch or 3.5-inch hard disks. Any one of the first container 11 or the second container 12 further has a latch 120. In other words, the latch 120 may be disposed on either the first container 11 or the second container 12, or on both the first container 11 and the second container 12. The latch 120 is used for latching/ejecting the hard disk 21 and/or the hard disk 22 from the first container 11 and/or the second container 12.

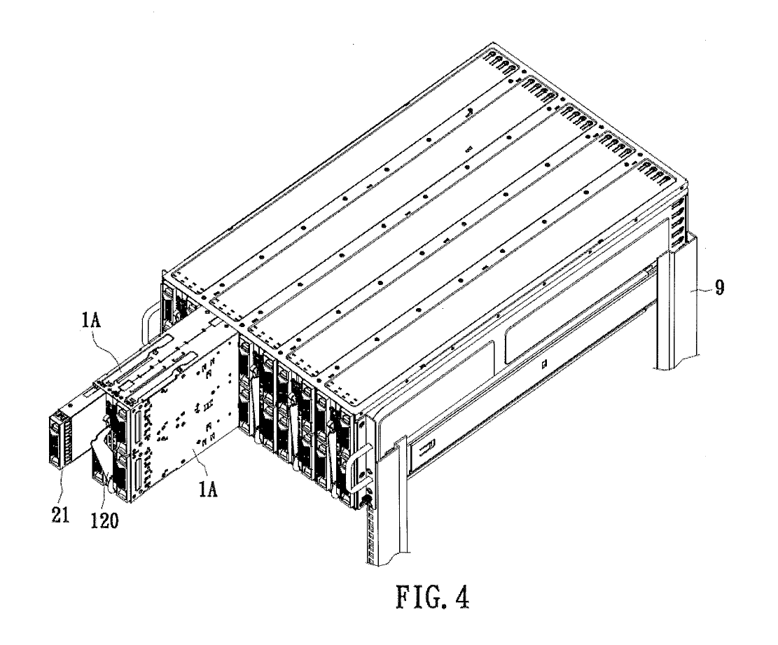

The latch 120 includes a driving portion 121 and a manual portion 122. The driving portion 121 and the manual portion 122 are hooked to each other, and the driving portion 121 is hooked on the hard disk 21. As illustrated in FIG. 4 and FIG. 1B, if a user wants to eject the hard disk 21, the user only needs to press the manual portion 122. With the rotation of the axial shaft 123, the driving portion 121 is moved and taken off the hook of the manual portion 122. Then the hard disk 21 is ejected.

Please refer to FIG. 1A to 1D. Under different requirements, the base 1 for node modules can be used for disposing different system allocation units (marked as 15 and 15′ in FIG. 1A and FIG. 1B) and forms different node modules 1A-1D. In the example of FIG. 1A, two motherboards are disposed in the base 1 to form a multiple motherboards computing structure. In the example of FIG. 1B, multiple storage units are disposed for high volume storage. In the example of FIG. 1C, a general purpose computing on graphics processing unit (GPGPU) is disposed for improving graphic computation. In the example of FIG. 1D, a small form factor PCI Express module (SXM) is disposed to be extendible. These node modules can be high performance computation modules for providing a rack with better computation power.

The node module 1A of FIG. 1A can be rotated with the rotation portion 13 of the base 1 for a folding rotation. As illustrated in FIG. 2, although the total size of the height H is changed from 1U to 2U and the length L is not changed, the width W is apparently reduced. Therefore, for server racks, such design provides more variation possibilities.

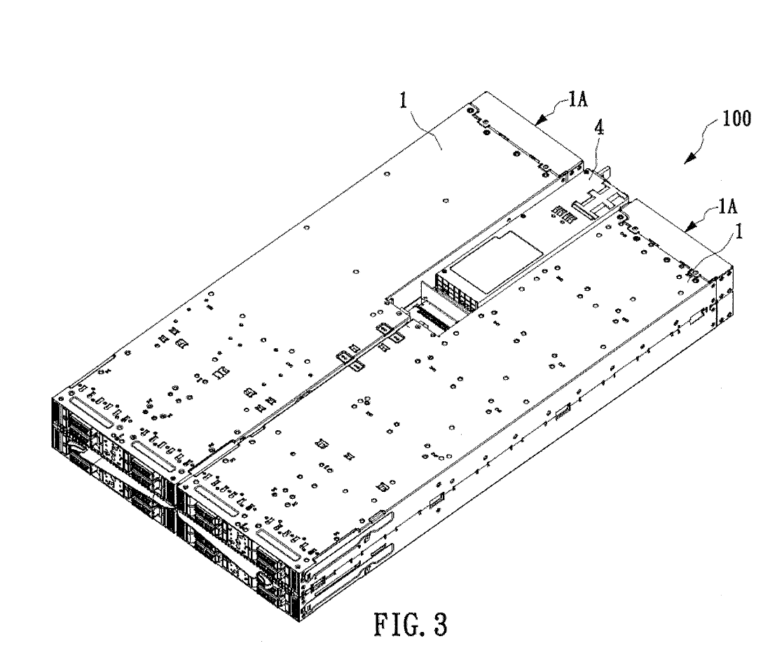

Please refer to FIG. 3. The present invention also provides a node module 100, which includes two bases 1 of the aforementioned node modules and a power supply 4. The power supply 4 is disposed between the two bases 1 for providing power to each system allocation unit. More specifically, when the bases 1 are disposed with different electronic boards and form different node modules like node module 1A, the power supply 100 is disposed between two node modules 1A for providing power to the node modules 1A. Therefore, as illustrated in FIG. 3, although the height is only 2U, it is two sets of 2U and forms a 4U arrangement, greatly improvingly the density of server racks.

Please refer to FIG. 4. In FIG. 4, multiple 2U node modules 1A are disposed on a rack shelf 9, and the structure of the base 1 facilitates loading and unloading from the case of the servers. In addition, as mentioned above, the latch 120 is used for ejecting or latching the hard disk 21. Therefore, the base 1 of the present invention provides a user with more flexible application.

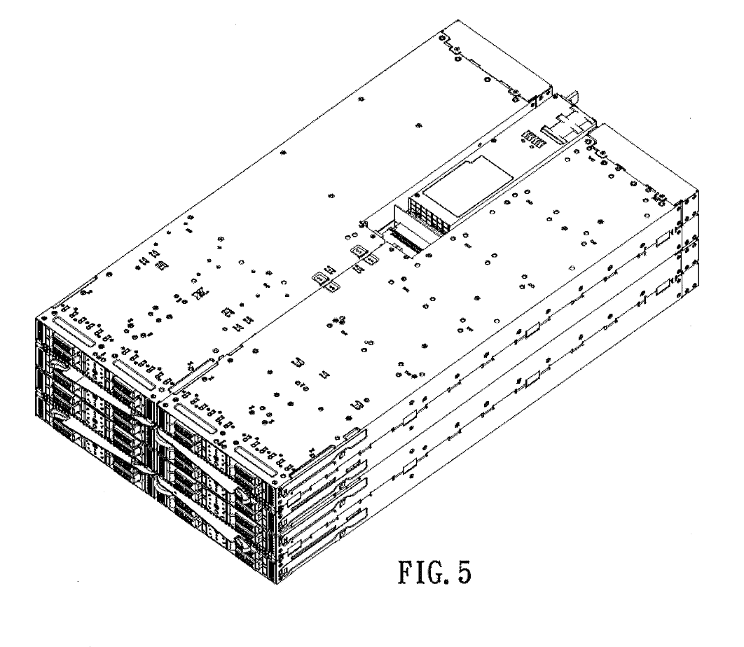

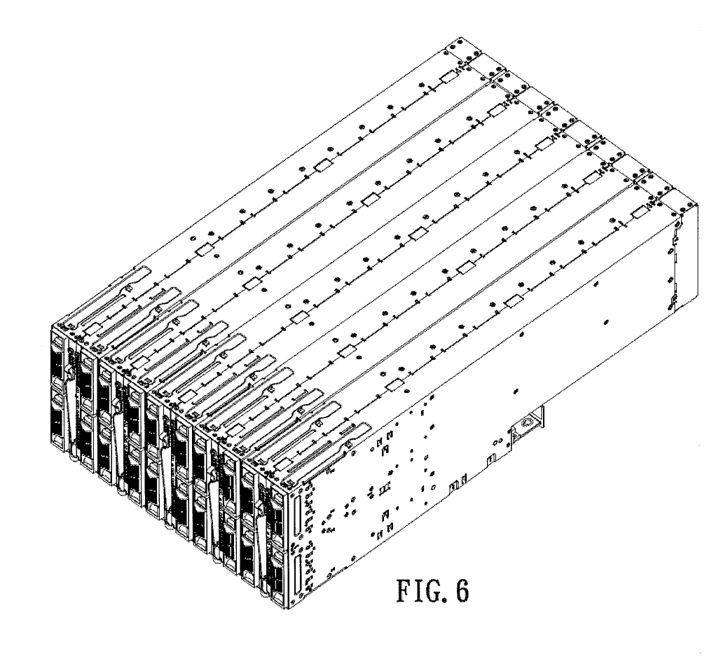

If a user needs more than 2U node modules 1A, the user may use multiple sets of the present invention, as illustrated in FIG. 5 and FIG. 6, which are four sets of 2U forming a 8U node module or are five sets of 2U forming a 10U node module. Please be noted that the numbers illustrated in the drawings are not used to limit the scope of the present invention. Persons of ordinary skill in the art may develop certain variations after reading the disclosure of the present invention.

The foregoing descriptions of embodiments of the present invention have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention. The scope of the present invention is defined by the appended claims.

What is claimed is:

1. A base of a node module, comprising:
a first container for disposing a system allocation unit of the node module;
a second container for disposing another system allocation unit of the node module, the second container being substantially the same as the first container, and the first container is adjacent to the second container; and
a rotation portion connected to the first container and the second container respectively such that the first container is able to be rotated with respect to the second container and to be stacked on the second container.

2. According to the base of claim 1, wherein a total height of the first container and the second container is 2U after being stacked.

3. According to the base of claim 1 further comprising a fan being disposed on the first container or the second container.

4. According to the base of claim 1, wherein a first hard disk and a second hard disk are respectively disposed in the first container and the second container, and any one of the first container and the second container further comprises a latch for controlling the exit of the first hard disk or the second hard disk from the first container or the second container.

5. According to the base of claim 1, wherein each of the first container and the second container has one side slightly wider than the other side, and when the first container and the second container are aligned without being rotated and stacked, the first container and the second container together form a slight T-shape.

6. A system allocation module comprising a base of claim 1, wherein the first container and the second container are respectively used for disposing any one of the following: a multiple motherboards computing unit, a general purpose computing on graphics processing unit (GPGPU), a storage unit, and a small form factor PCI Express Module (SXM) unit.

7. A node module, comprising:
a power supply;
a plurality of system allocation units; and
two bases of claim 1 for disposing the plurality of system allocation units, wherein the power supply is located between the two bases for providing power to each of the system allocation units.

8. According to the node module of claim 7, wherein the plurality of system allocation units at least comprises a multiple motherboards computing unit.

9. According to the node module of claim 7, wherein the plurality of system allocation units at least comprises a general purpose computing on graphics processing unit (GPGPU).

10. According to the node module of claim 7, wherein the plurality of system allocation units at least comprises a storage unit.

11. According to the node module of claim 7, wherein the plurality of system allocation units at least comprises a small form factor PCI Express module (SXM) unit.
